(19) United States
(12) Patent Application Publication
(10) Pub. No.: US 2017/0131374 A1
(43) Pub. Date: May 11, 2017

(54) MAGNETIC RESONANCE IMAGING APPARATUS AND IMAGE PROCESSING METHOD THEREOF

(71) Applicants: SAMSUNG ELECTRONICS CO., LTD., Suwon-si (KR); SEOUL NATIONAL UNIVERSITY R&DB FOUNDATION, Seoul (KR)

(72) Inventors: Sang-cheon CHOI, Suwon-si (KR); Jongho LEE, Seoul (KR); Jeehun KIM, Seoul (KR); Yoonho NAM, Seoul (KR)

(73) Assignees: SAMSUNG ELECTRONICS CO., LTD., Suwon-si (KR); SEOUL NATIONAL UNIVERSITY R&DB FOUNDATION, Seoul (KR)

(21) Appl. No.: 15/347,110

(22) Filed: Nov. 9, 2016

(30) Foreign Application Priority Data
Nov. 10, 2015 (KR) 10-2015-0157488
Oct. 10, 2016 (KR) 10-2016-0130830

(51) Int. Cl. G01R 33/48; G01R 33/567

(52) U.S. Cl. CPC G01R 33/4818; G01R 33/4828; G01R 33/5673

(57) ABSTRACT

A magnetic resonance imaging (MRI) apparatus, including a scanner configured to emit at least one radio frequency (RF) signal to an object during one repetition time (TR), and to receive echo signals emitted from the object; and a controller configured to transmit one or more control signals to the scanner to control the scanner, wherein the controller may be further configured to control the scanner to emit an RF excitation pulse and a refocusing pulse to the object during the one TR, control the scanner to receive a first echo signal corresponding to a first line of a k-space before an echo time (TE), and to receive a second echo signal corresponding to a second line of the k-space after the TE, and reconstruct a magnetic resonance (MR) image based on the k-space.

### CROSS-REFERENCE TO RELATED APPLICATION

This application claims benefit from Korean Patent Applications No. 10-2015-0157488, filed on Nov. 10, 2015, and No. 10-2016-0130830, filed on Oct. 10, 2016, in the Korean Intellectual Property Office, the disclosures of which are incorporated herein in their entireties by reference.

### BACKGROUND

1. Field

The present disclosure relates to methods of obtaining echo signals and generating magnetic resonance (MR) images to construct the MR images by using magnetic resonance imaging (MRI) apparatuses, and MRI apparatuses used to perform the methods.

2. Description of the Related Art

A magnetic resonance imaging (MRI) apparatus that is an apparatus for imaging a subject by using a magnetic field is widely used to accurately diagnose a disease because the MRI apparatus shows not only bones but also a slipped disc, joints, nerves, ligaments, etc. at desired angles in a three-dimensional (3D) manner.

However, it takes a long time to obtain a magnetic resonance (MR) image by using an MRI apparatus. Also, when a time taken to obtain an image increases, distortion may occur due to a movement such as heartbeat, respiration, or peristalsis, thereby making it difficult to obtain a high-quality image. Accordingly, there is a demand for a method and apparatus for reducing a time taken to obtain an image.

### SUMMARY

Provided are magnetic resonance imaging (MRI) apparatuses and methods of generating magnetic resonance (MR) images based on spin-echo methods by using the MRI apparatuses.

Additional aspects will be set forth in part in the description which follows and, in part, will be apparent from the description, or may be learned by practice of the presented exemplary embodiments.

According to an aspect of an exemplary embodiment, a magnetic resonance imaging (MRI) apparatus includes a scanner configured to emit at least one radio frequency (RF) signal to an object during one repetition time (TR), and to receive echo signals emitted from the object; and a controller configured to transmit one or more control signals to the scanner to control the scanner, wherein the controller may be further configured to control the scanner to emit an RF excitation pulse and a refocusing pulse to the object during the one TR, control the scanner to receive a first echo signal corresponding to a first line of a k-space before an echo time (TE), and to receive a second echo signal corresponding to a second line of the k-space after the TE, and reconstruct a magnetic resonance (MR) image based on the k-space.

The first echo signal may include a first partial echo signal biased in a first direction of the k-space, and the second echo signal may include a second partial echo signal biased in a second direction of the k-space.

The controller may be further configured to bias and sample the first echo signal in the first direction corresponding to the first line of the k-space and bias and sample the second echo signal in the second direction corresponding to the second line of the k-space.

The controller may be further configured to control the scanner to apply a first readout gradient magnetic field to the object for receiving the first echo signal, and a second readout gradient magnetic field to the object for receiving the second echo signal.

The first readout gradient magnetic field may include a first bipolar gradient magnetic field for receiving an echo signal corresponding to a central region of the k-space a predetermined period of time before the TE, and the second readout gradient magnetic field may include a second bipolar gradient magnetic field for receiving an echo signal corresponding to the central region of the k-space the predetermined period of time after the TE.

The first line may be discontinuous with the second line in the k-space.

The controller may be further configured to reconstruct the MR image by interpolating non-sampled regions in the k-space, based on a projection of convex set (POCS) method.

The first line may be continuous with the second line in the k-space.

The controller may be further configured to reconstruct a first MR image from lines biased in a first direction of the k-space, and reconstruct a second MR image from lines biased in a second direction of the k-space, based on a two-point Dixon method.

The first echo signal may be received before a first TE in which magnetization between water and fat in the object is in-phase, and the second echo signal may be received after a second TE in which magnetization between water and fat in the object is out of phase.

According to another aspect of an exemplary embodiment, an operation method of a magnetic resonance imaging (MRI) apparatus includes emitting a radio frequency (RF) excitation pulse and a refocusing pulse to an object during one repetition time (TR), receiving a first echo signal corresponding to a first line of a k-space before an echo time (TE), and receiving a second echo signal corresponding to a second line of the k-space after the TE, and reconstructing a magnetic resonance (MR) image based on the k-space.

The first echo signal may include a first partial echo signal biased in a first direction of the k-space, and the second echo signal may include a second partial echo signal biased in a second direction of the k-space.

The receiving of the first echo signal and the second echo signal may include: biasing and sampling the first echo signal in the first direction corresponding to the first line of the k-space, and biasing and sampling the second echo signal in the second direction corresponding to the second line of the k-space.

The operation method may include further applying a first readout gradient magnetic field to the object for receiving the first echo signal, and a second readout gradient magnetic field to the object for receiving the second echo signal.

he first readout gradient magnetic field may include a first bipolar gradient magnetic field for receiving an echo signal corresponding to a central region of the k-space a predetermined period of time before the TE, and the second readout gradient magnetic field may include a second bipolar gradient magnetic field for receiving an echo signal corresponding to the central region of the k-space the predetermined period of time after the TE.

The first line may be discontinuous with the second line in the k-space.

The reconstructing of the MR image may include reconstructing the MR image by interpolating non-sampled regions in the k-space, based on a projection of convex set (POCS) method.

The first line may be continuous with the second line in the k-space.

The reconstructing of the MR image may include reconstructing a first MR image from lines biased in a first direction of the k-space and reconstructing a second MR image from lines biased in a second direction of the k-space, based on a two-point Dixon method.

According to yet another aspect of an exemplary embodiment, a computer-readable recording medium may have embodied thereon a program for executing the operation method.

### BRIEF DESCRIPTION OF THE DRAWINGS

These and other aspects will become apparent and more readily appreciated from the following description of the exemplary embodiments, taken in conjunction with the accompanying drawings in which:

FIG. 1 is a schematic diagram of a magnetic resonance imaging (MRI) system;

FIG. 2 is a block diagram illustrating a configuration of an MRI apparatus according to an exemplary embodiment;

FIG. 3 is a diagram illustrating an example where a dual-echo signal received during one repetition time (TR) is biased and sampled in a kx-axis direction of a k-space;

FIG. 4 is a detailed diagram illustrating a pulse sequence according to an exemplary embodiment;

FIG. 5 is a diagram illustrating a k-space obtained by a controller during a scan time, according to an exemplary embodiment;

FIG. 6 is a diagram illustrating a k-space obtained by the controller during a scan time, according to another exemplary embodiment;

FIG. 7 is a diagram illustrating an example where the controller reconstructs magnetic resonance (MR) images based on the k-space of FIG. 6;

FIG. 8 is a diagram illustrating another example where the MRI apparatus reconstructs an MR image, according to an exemplary embodiment; and

FIG. 9 is a flowchart of an operation method of the MR apparatus, according to an exemplary embodiment.

### DETAILED DESCRIPTION

The present specification describes principles of the present disclosure and sets forth exemplary embodiments thereof to clarify the scope of the present disclosure and to allow those of ordinary skill in the art to implement the embodiments. The present exemplary embodiments may have different forms and should not be construed as being limited to the descriptions set forth herein.

Like reference numerals refer to like elements throughout. The present specification does not describe all components in the exemplary embodiments, and common knowledge in the art or the same descriptions of the exemplary embodiments will be omitted below. The term “part” or “portion” may be implemented using hardware or software, and according to exemplary embodiments, one “part” or “portion” may be formed as a single unit or element or include a plurality of units or elements. Expressions such as “at least one of,” when preceding a list of elements, modify the entire list of elements and do not modify the individual elements of the list. Hereinafter, the principles and exemplary embodiments of the present disclosure will be described in detail with reference to the accompanying drawings.

In the present specification, an “image” may include a medical image obtained by using a medical imaging apparatus such as a magnetic resonance imaging (MRI) apparatus, a computed tomography (CT) apparatus, an ultrasound imaging apparatus, or an X-ray apparatus.

Furthermore, in the present specification, an ‘object’ may be a target to be imaged and include a human, an animal, or a part of a human or animal. For example, the object may include a body part (e.g., an organ) or a phantom.

An MRI system acquires a magnetic resonance (MR) signal and reconstructs the acquired MR signal into an image. The MR signal denotes a radio frequency (RF) signal emitted from the object.

In the MRI system, a main magnet creates a static magnetic field to align a magnetic dipole moment of a specific atomic nucleus of the object placed in the static magnetic field along a direction of the static magnetic field. A gradient coil may generate a gradient magnetic field by applying a gradient signal to a static magnetic field and induce resonance frequencies differently according to regions of the object.

An RF coil may emit an RF signal to match a resonance frequency of a region of the object whose image is to be acquired. Furthermore, when gradient magnetic fields are applied, the RF coil may receive MR signals having different resonance frequencies emitted from a plurality of regions of the object. Though this process, the MRI system obtains an image from an MR signal by using an image reconstruction technique.

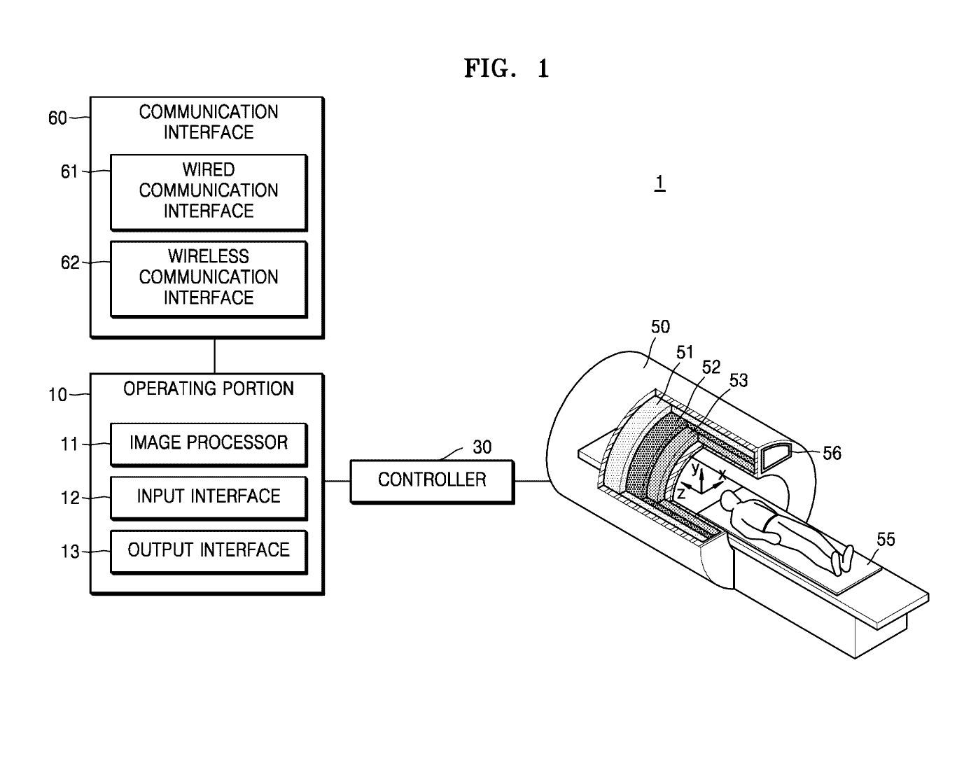

FIG. 1 is a schematic diagram of an MRI system 1. Referring to FIG. 1, the MRI system 1 may include an operating portion 10, a controller 30, and a scanner 50. The controller 30 may be independently formed as shown in FIG. 1. Alternatively, the controller 30 may be separated into a plurality of components and included in elements of the MRI system 1. Operations of the elements of the MRI system 1 will now be described in detail.

The scanner 50 may be formed to have a cylindrical shape (e.g., a bore shape) having an empty inner space into which an object may be inserted. A static magnetic field and a gradient magnetic field are created in the inner space of the scanner 50, and an RF signal is emitted toward the inner space.

The scanner 50 may include a static magnetic field generator 51, a gradient magnetic field generator 52, an RF coil 53, a table 55, and a display 56. The static magnetic field generator 51 creates a static magnetic field for aligning magnetic dipole moments of atomic nuclei of the object in a direction of the static magnetic field. The static magnetic field generator 51 may be formed as a permanent magnet or a superconducting magnet using a cooling coil.

The gradient magnetic field generator 52 is connected to the controller 30 and generates a gradient magnetic field by applying a gradient to a static magnetic field in response to a control signal received from the controller 30. The gradient magnetic field generator 52 includes X, Y, and Z coils for generating gradient magnetic fields in X-, Y-, and Z-axis directions crossing each other at right angles and generates a gradient signal according to a position of a region being imaged so as to differently induce resonance frequencies according to regions of the object.

The RF coil 53 may be connected to the controller 30, and may emit an RF signal toward the object in response to a control signal received from the controller 30 and receive an MR signal emitted from the object. In detail, the RF coil 53 may transmit, toward atomic nuclei of the object having precessional motion, an RF signal having the same frequency as that of the precessional motion, stop transmitting the RF signal, and then receive an MR signal emitted from the object.

The RF coil 53 may be formed as a transmitting RF coil for generating an electromagnetic wave having an RF corresponding to a type of an atomic nucleus, a receiving RF coil for receiving an electromagnetic wave emitted from an atomic nucleus, or one transmitting/receiving RF coil serving both functions of the transmitting RF coil and receiving RF coil. Furthermore, in addition to the RF coil 53, a separate coil may be attached to the object. Examples of the separate coil may include a head coil, a spine coil, a torso coil, and a knee coil according to a region being imaged or to which the separate coil is attached.

The display 56 may be disposed outside and/or inside the scanner 50. The display 56 is also controlled by the controller 30 to provide a user or the object with information related to medical imaging.

Furthermore, the scanner 50 may include an object monitoring information acquirer configured to acquire and transmit monitoring information about a state of the object. For example, the object monitoring information acquirer may acquire monitoring information related to the object from a camera for capturing images of a movement or position of the object, a respiration measurer for measuring the respiration of the object, an electrocardiogram (ECG) measurer for measuring an electrical activity of the heart, or a temperature measurer for measuring a temperature of the object and transmit the acquired monitoring information to the controller 30. The controller 30 may in turn control an operation of the scanner 50 based on the monitoring information. The controller 30 will now be described in more detail.

The controller 30 may control overall operations of the scanner 50.

The controller 30 may control a sequence of signals formed in the scanner 50. The controller 30 may control the gradient magnetic field generator 52 and the RF coil 53 according to a pulse sequence received from the operating portion 10 or a designed pulse sequence.

A pulse sequence may include all pieces of information required to control the gradient magnetic field generator 52 and the RF coil 53. For example, the pulse sequence may include information about a strength, a duration, and an application timing of a pulse signal applied to the gradient magnetic field generator 52.

The controller 30 may control the gradient magnetic field generator 52 to create a gradient magnetic field by controlling a waveform generator for generating a gradient waveform, i.e., a current pulse, according to a pulse sequence and a gradient amplifier for amplifying the generated current pulse and transmitting the same to the gradient magnetic field generator 52.

The controller 30 may control an operation of the RF coil 53. For example, the controller 30 may supply an RF pulse having a resonance frequency to the RF coil 53 that emits an RF signal, and receive an MR signal received by the RF coil 53. In this case, the controller 30 may adjust emission of an RF signal and reception of an MR signal according to an operating mode by controlling an operation of a switch (e.g., a T/R switch) for adjusting transmitting and receiving directions of the RF signal and the MR signal based on a control signal.

The controller 30 may control a movement of the table 55 where the object is placed. Before MRI is performed, the controller 30 may move the table 55 according to a region of the object to be imaged.

The controller 30 may also control the display 56. For example, the controller 30 control the display 56 to be turned on or off or a screen to be output on the display 56 according to a control signal.

The controller 30 may be formed as an algorithm for controlling operations of the components in the MRI system 1, a memory for storing data in the form of a program, and a processor for performing the above-described operations by using the data stored in the memory. In this case, the memory and the processor may be implemented as separate chips. Alternatively, the memory and processor may be incorporated into a single chip.

The operating portion 10 may control overall operations of the MRI system 1 and include an image processor 11, an input interface 12, and an output interface 13.

The image processor 11 may control the memory to store an MR signal received from the controller 30, and generate image data about the object from the stored MR signal by using an image reconstruction technique.

For example, if a k-space (for example, also referred to as a Fourier space or a frequency space) of the memory is filled with digital data to complete k-space data, the image processor 11 may reconstruct image data from the k-space data by using various image reconstruction techniques (e.g., by performing inverse Fourier transform on the k-space data).

Furthermore, the image processor 11 may perform various signal processing operations on MR signals in parallel. For example, the image processor 11 may perform signal processing on a plurality of MR signals received via a multi-channel RF coil in parallel so as to convert the plurality MR signals into image data. In addition, the image processor 11 may store the image data in the memory, or the controller 30 may store the image data in an external server via a communication interface 60 as will be described below.

The input interface 12 may receive, from the user, a control command for controlling the overall operations of the MRI system 1. For example, the input interface 12 may receive, from the user, object information, parameter information, a scan condition, and information about a pulse sequence. The input interface 12 may be a keyboard, a mouse, a track ball, a voice recognizer, a gesture recognizer, a touch screen, or any other input interface.

The output interface 13 may output image data generated by the image processor 11. The output interface 13 may also output a user interface (UI) configured so that the user may receive a control command related to the MRI system 1. The output interface 13 may be formed as a speaker, a printer, a display, or any other output interface.

Although FIG. 1 shows that the operating portion 10 and the controller 30 are separate components, the operating portion 10 and the controller 30 may be included in a single device as described above. Furthermore, processes performed by the operating portion 10 and the controller 30 may be performed by another component. For example, the image processor 11 may convert an MR signal received from the controller 30 into a digital signal, or the controller 30 may directly perform the conversion of the MR signal into the digital signal.

The MRI system 1 may include the communication interface 60 and be connected to an external device such as a server, a medical apparatus, or a portable device (e.g., a smartphone, a tablet PC, or a wearable device) via the communication interface 60.

The communication interface 60 may include at least one component that enables communication with an external device. For example, the communication interface 60 may include at least one of a local area communication module, a wired communication interface 61, and a wireless communication interface 62.

The communication interface 60 may receive a control signal and data from an external device and transmit the received control signal to the controller 30 so that the controller 30 may control the MRI system 1 according to the received control signal.

Alternatively, the controller 30 may control an external device according to a control signal by transmitting the control signal to the external device via the communication interface 60.

For example, the external device may process data according to a control signal received from the controller 30 via the communication interface 60.

A program for controlling the MRI system 1 may be installed on the external device and may include instructions for performing some or all of operations of the controller 30.

The program may be pre-installed on the external device, or a user of the external device may download the program from a server that provides an application. The server that provides the application may include a recording medium having the program recorded thereon.

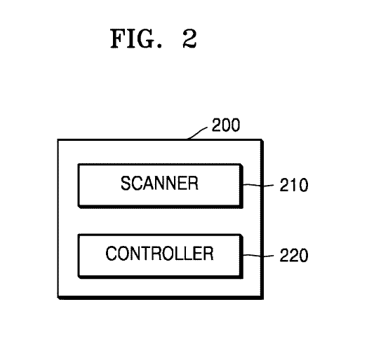

FIG. 2 is a block diagram illustrating a configuration of an MRI apparatus 200 according to an exemplary embodiment.

According to an exemplary embodiment, the MRI apparatus 200 may be any image processing apparatus for reconstructing an MR image by using an MR signal obtained through MRI. Also, the MRI apparatus 200 may be a magnetic computing apparatus for controlling acquisition of an MR signal through MRI.

Referring to FIG. 2, the MRI apparatus 200 according to an exemplary embodiment may include a scanner 210 and a controller 220.

In detail, the MRI apparatus 200 may be included in the MRI system 1 of FIG. 1. In this case, the scanner 210 and the controller 220 of the MRI apparatus 200 may respectively correspond to the scanner 50 and the controller 30 of FIG. 1. Also, according to an exemplary embodiment, the controller 220 of FIG. 2 may further perform a function of the image processor 11 of FIG. 1. Alternatively, the MRI apparatus 20 may be a computing apparatus that is connected to the MRI system 1 of FIG. 1 and may control an MRI operation in the MRI system 1. In this case, the scanner 210 of the MRI apparatus 200 may be omitted, and the MRI apparatus 200 may further include a communication interface for communicating with the scanner 50 of the MRI system 1 of FIG. 1.

According to an exemplary embodiment, the scanner 210 includes one or more elements for creating a static magnetic field and a gradient magnetic field in the scanner 210 and emitting an RF signal under the control of the controller 220. Also, the scanner 210 may receive MR signals emitted from an object and may apply the MR signals to the controller 220, which has been described with reference to FIG. 1 and thus will not be described in detail.

According to an exemplary embodiment, the controller 220 may control the scanner 210 to emit at least one RF excitation pulse and at least one RF refocusing pulse to the object. For example, the controller 220 may determine a size, a direction, and a timing of each of the at least one RF excitation pulse and the at least one refocusing pulse emitted to the object and may transmit a control signal corresponding to determined information to the scanner 210.

For example, the controller 220 may determine a size, a direction, and a timing of the RF excitation pulse and the refocusing pulse emitted to the object based on a spin-echo (SE) method. The SE method may be a method of receiving an echo signal (i.e., an MR signal) by using magnetization in which when an RF exciting pulse having an angle of 90° is applied to specific tissue of the object and then dephasing of atoms in the specific tissue is performed, an RF refocusing pulse having an angle of 180° is applied so that the atoms in the specific tissue precess in phase in opposite directions. According to an exemplary embodiment, the controller 220 may control the scanner 210 to receive a dual-echo signal before and after an echo time (TE) during one repetition time (TR). The TR may refer to a time at which an eco signal having a highest intensity is measured after an RF pulse is applied to an object.

In detail, the controller 220 may receive a first echo signal corresponding to a first line of a k-space before a TE and may receive a second echo signal corresponding to a second line of the k-space after the TE. In this case, the first echo signal and the second echo signal may be partial echo signals that are biased in different directions of the k-space. Accordingly, the controller 220 may fill a part of the first line and a part of the second line in the k-space by sampling the first echo signal and the second echo signal. For example, the first echo signal may be biased and sampled in a first direction (e.g., a negative (−) direction) of a kx-axis of the k-space, and the second echo signal may be biased and sampled in a second direction (e.g., a positive (+) direction) of the kx-axis of the k-space.

According to an exemplary embodiment, the controller 220 may control a first readout gradient magnetic field and a second readout gradient magnetic field to be created in the scanner 210 before and after a TE in order to respectively receive the first echo signal and the second echo signal that are biased and sampled in different directions. Each of the first and second readout gradient magnetic field may be a gradient magnetic field corresponding to the kx-axis of the k-space, for example, a frequency encoding gradient magnetic field.

The controller 220 may adjust the first readout gradient magnetic field and the second readout gradient magnetic field in order to receive the first echo signal and the second echo signal having high intensities in a central region of the k-space (e.g., a part where the kx-axis and a ky-axis of the k-space intersect each other). For example, the first readout gradient magnetic field may include a first bipolar gradient magnetic field for receiving the first echo signal corresponding to the central region of the k-space a predetermined period of time (e.g., Δt) before the TE, and a second bipolar gradient magnetic field for receiving the second echo signal corresponding to the central region of the k-space the predetermined period of time (e.g., Δt) after the TE. The controller 220 may control the first echo signal and the second echo signal not to lose their intensities in the central region of the k-space by adjusting the predetermined period of time (e.g., Δt). For example, the controller 220 may control the first echo signal and the second echo signal to be received at a time close to the TE by reducing the predetermined period of time.

The controller 220 may adjust a position of the first line corresponding to the first echo signal in the k-space and a position of the second line corresponding to the second echo signal in the k-space by controlling a magnitude and a direction of a phase encoding gradient magnetic field. For example, the controller 220 may control the phase encoding gradient magnetic field so that the first line and the second line are discontinuous in the k-space in order to reduce magnetic field inhomogeneity or phase discontinuity. Alternatively, the controller 220 may control the phase encoding gradient magnetic field so that the first line and the second line are continuous in the k-space.

According to an exemplary embodiment, the controller 220 may determine a method of reconstructing an MR image according to whether the first line and the second line are continuous. For example, the controller 220 may reconstruct an MR image based on a projection of convex set (POCS) method when the first line that is filled by the first echo signal in the k-space and the second line that is filled by the second echo signal are discontinuous. Alternatively, the controller 220 may reconstruct an MR image based on a two-point Dixon method when the first line corresponding to the first echo signal in the k-space and the second line corresponding to the second echo signal in the k-space are continuous. In this case, the controller 220 may reconstruct a first MR image based on lines that are filled in the k-space by the first echo signals and may reconstruct a second MR image based on lines that are filled in the k-space by the second echo signals.

The controller 220 may control the scanner 210 to emit one RF excitation pulse and a plurality of refocusing pulses to the object based on a fast spin-echo (FSE) method. In this case, the controller 220 may obtain a plurality of dual-echo signals by controlling the scanner 210 to create readout gradient magnetic fields before and after each of a plurality of TEs. For example, when N refocusing pulses are emitted to the object, the controller 220 may receive 2×N echo signals corresponding to 2×N lines in the k-space. Also, the controller 220 may fill the 2×N lines in the k-space based on the 2×N echo signals.

Although the readout gradient magnetic field is a frequency encoding gradient magnetic field in the above, exemplary embodiments are not limited thereto. According to an exemplary embodiment, the readout gradient magnetic field may be a phase encoding gradient magnetic field. In this case, a method used by the controller 220 to control a frequency encoding gradient magnetic field may also be used to control a phase encoding gradient magnetic field, and a method used to control a phase encoding gradient magnetic field may be used to control a frequency encoding gradient magnetic field.

As such, the MRI apparatus 200 according to an exemplary embodiment may reconstruct a high-quality MR image according to an SE method while reducing a scan time.

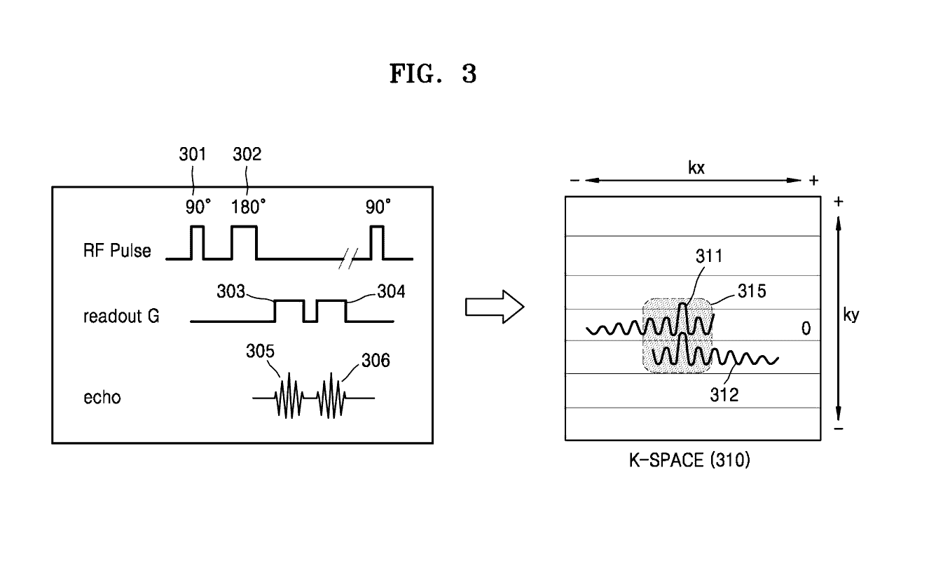

FIG. 3 is a diagram illustrating an example where a dual-echo signal received during one TR is biased and sampled in a kx-axis direction of a k-space.

Referring to FIG. 3, the controller 220 may control the scanner 210 to emit a 90°-RF excitation pulse 301 and a 180°-refocusing pulse 302 to an object during one TR and then to apply a first readout gradient magnetic field 303 for receiving a first echo signal 305 and a second readout gradient magnetic field 304 for receiving a second echo signal 306 to the object.

According to an exemplary embodiment, the controller 220 may control the first readout gradient magnetic field 303 for biasing and sampling the first echo signal 305 in a negative (−) direction on a first line of the k-space 310 to be applied to the object as shown in 311 of FIG. 3. Also, the controller 220 may control the second readout gradient magnetic field 304 for biasing and sampling the second echo signal 306 in a positive (+) direction on a second line of the k-space 310 to be applied to the objet as shown in 312 of FIG. 3.

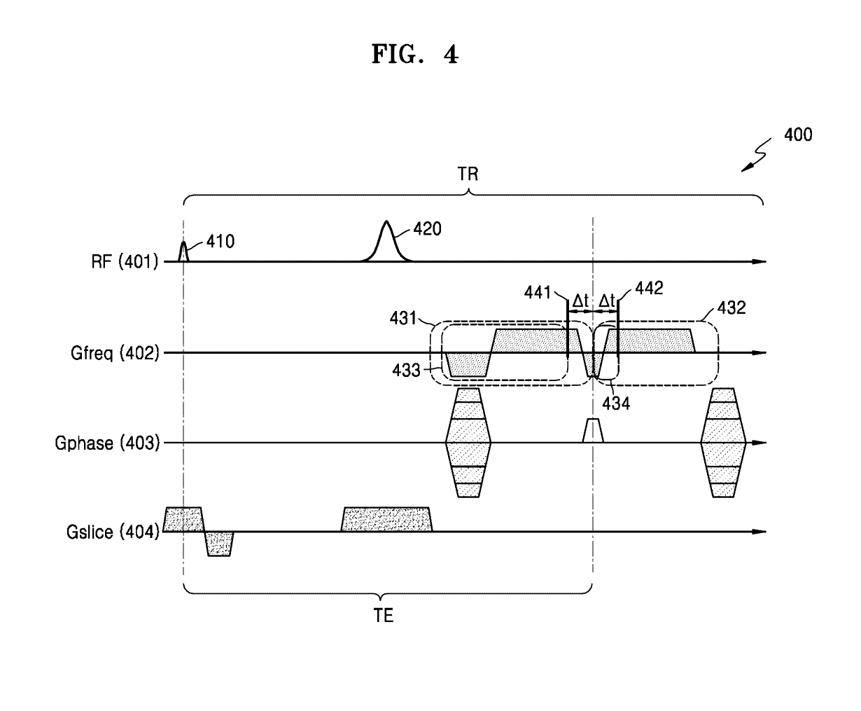

Also, the controller 220 may adjust the first readout gradient magnetic field 303 and the second readout gradient magnetic field 304 in order to increase intensities of the first echo signal 305 and the second echo signal 306 corresponding to a central region 315 (i.e., a part where a kx-axis and a ky-axis intersect each other) of the k-space, which will be explained in detail with reference to FIG. 4.

FIG. 4 is a detailed diagram of a pulse sequence 400 according to an exemplary embodiment.

Referring to FIG. 4, the controller 220 may obtain a dual-echo signal (i.e., a first echo signal and a second echo signal) during one TR by controlling the scanner 210 according to the pulse sequence 400. The pulse sequence 400 may include information about an RF pulse 401 emitted by the scanner 210 to an object under the control of the controller 220, information about a frequency encoding gradient magnetic field 402, information about a phase encoding gradient magnetic field 403, and a slice selection gradient magnetic field 404. The slice selection gradient magnetic field 404 may be used to determine a target position of the object scanned by the MRI apparatus 200. Also, the frequency encoding gradient magnetic field 402 may function as a readout gradient magnetic field.

In detail, the pulse sequence 400 may include a first frequency encoding gradient magnetic field 431 for receiving the first echo signal that is biased and sampled in a negative direction of a kx-axis of a k-space before a TE. The first frequency encoding gradient magnetic field 431 may include a bipolar gradient magnetic field 433 for determining a first timing 441 at which the first echo signal corresponding to a central region of the k-space is received. In this case, a sum of moments (μ) of the first bipolar gradient magnetic field 433 may be 0.

Also, the pulse sequence 400 may include a second frequency encoding gradient magnetic field 432 for receiving the second echo signal that is biased and sampled in a positive direction of the kx-axis of the k-space after the TE. The second frequency encoding gradient magnetic field 432 may include a second bipolar gradient magnetic field 434 for determining a second timing 442 at which the second echo signal corresponding to the central region of the k-space is received. In this case, a sum of moments of the second bipolar gradient magnetic field 434 may be 0.

The first timing 441 and the second timing 442 may have the same or a similar time difference (e.g., Δt) from the TE. Accordingly, the controller 220 may obtain a high-quality MR image by receiving echo signals corresponding to the central region of the k-space the same (or a similar) period of time before and after the TE.

Also, the pulse sequence 400 may include the phase encoding gradient magnetic field 403 for determining positions of the first echo signal and the second echo signal received during one TR on a ky-axis. For example, the pulse sequence 400 may include the phase encoding gradient magnetic field 403 for receiving the first echo signal and the second echo signal that are sampled at discontinuous or continuous positions on the ky-axis during one TR. The phase encoding gradient magnetic field 403 of FIG. 4 is illustrated so that magnitudes and directions of encoding gradient magnetic fields applied to the object during a plurality of TRs overlap one another.

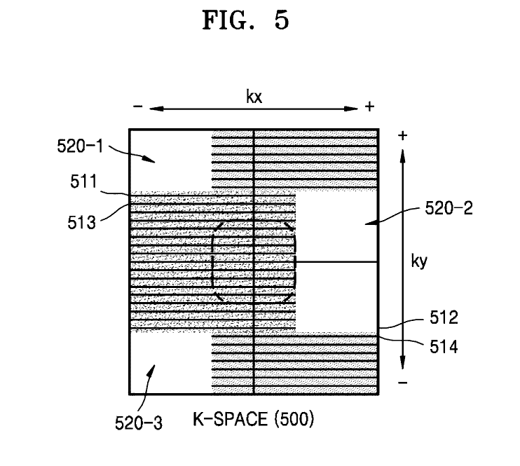

FIG. 5 is a diagram illustrating a k-space 500 obtained by the controller 220 during a scan time according to an exemplary embodiment.

Referring to FIG. 5, the controller 220 may receive first echo signals and second echo signals that are sampled to correspond to lines having discontinuous positions on a ky-axis of the k-space 500 during each of a plurality of TRs. For example, the controller 220 may fill a part 511 of an I^{th} line of the k-space 500 by using a first echo signal and may fill a part 512 of an X^{th} line by using a second echo signal received during an N^{th} TR. Also, the controller 220 may fill a part 513 of an (I+1)^{th} line of the k-space 500 by using a first echo signal and may fill a part 514 of an (X+1)^{th} line by using a second echo signal received during an (N+1)^{th} TR.

According to an exemplary embodiment, the controller 220 may reconstruct an MR image by interpolating pieces of data corresponding to non-sampled regions 520-1, 520-2, and 520-3 other than a central region 530 of the k-space 500. In detail, the controller 220 may reconstruct an MR image by interpolating pieces of data corresponding to the non-sampled regions 520-1, 520-2, and 520-3 of the k-space 500 based on a POCS method. The POCS method may be a method of interpolating pieces of data of non-sampled regions by repeatedly performing a process of reconstructing an MR image by using at least one projection data on the assumption that the non-sampled regions are regarded as missing data. The controller 220 may reconstruct an MR image by using a generalized autocalibrating partially parallel acquisition (GRAPPA) method or a sensitivity encoding (SENSE) method.

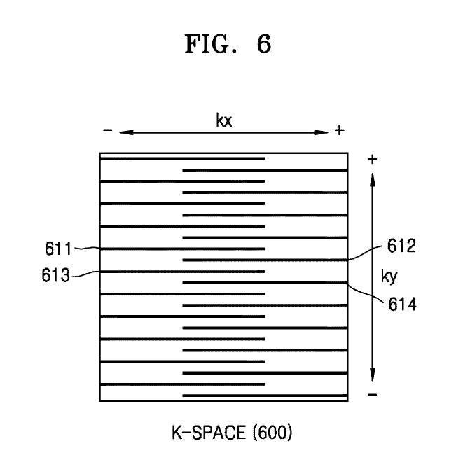

FIG. 6 is a diagram illustrating a k-space 600 obtained by the controller 220 during a scan time according to another exemplary embodiment.

Referring to FIG. 6, the controller 220 may receive first echo signals and second echo signals that are sampled to correspond to lines having continuous positions on a ky-axis of the k-space 600 during each of a plurality of TRs. For example, the controller 220 may fill a part 611 of an I^{th} line of the k-space 600 by using a first echo signal and may fill a part 612 of an (I+1)^{th} line by using a second echo signal received during an N^{th} TR. Also, the controller 220 may fill a part 613 of an (I+2)^{th} line of the k-space 600 by using a first echo signal and may fill a part 614 of an (I+3)^{th} line by using a second echo signal received during an (N+1)^{th} TR.

The controller 220 may reconstruct a first MR image from lines that are biased in a negative direction of the k-space 600 and may reconstruct a second MR image from lines that are biased in a positive direction of the k-space 600 based on a two-point Dixon method. The two-point Dixon method may be a method of obtaining separated MR images by using a phase difference between water and fat. Accordingly, the controller 220 may obtain the first echo signals based on a first TE in which magnetization between water and fat is in-phase and may obtain the second echo signals based on a second TE in which magnetization between water and fat is out of phase.

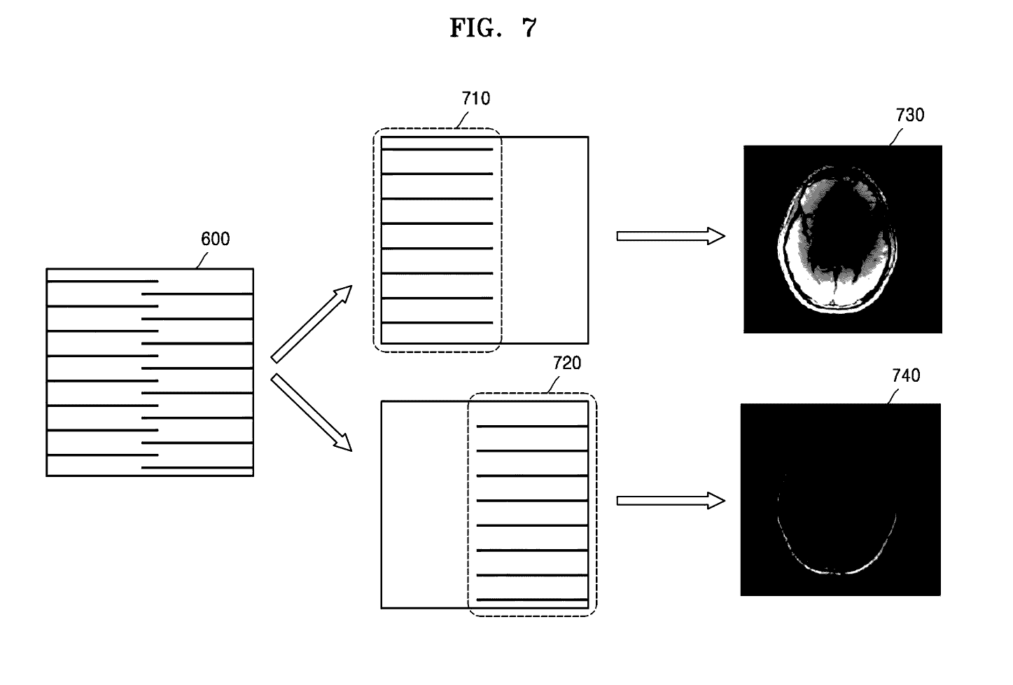

FIG. 7 is a diagram illustrating an example where the controller 220 reconstructs MR images based on the k-space 600 of FIG. 6.

Referring to FIG. 7, the controller 220 may reconstruct a first MR image 730 from lines 710 that are biased in a negative direction of the k-space 600. In this case, the MR image 730 may be a water-only image in which a fat component in an object is suppressed. Also, the controller 220 may reconstruct a second MR image 740 from lines 720 that are biased in a positive direction of the k-space 600. In this case, the second MR image 730 may be a fat-only image in which a water component in the object is suppressed.

The controller 220 may use a GRAPPA method or a SENSE method in order to reconstruct an MR image.

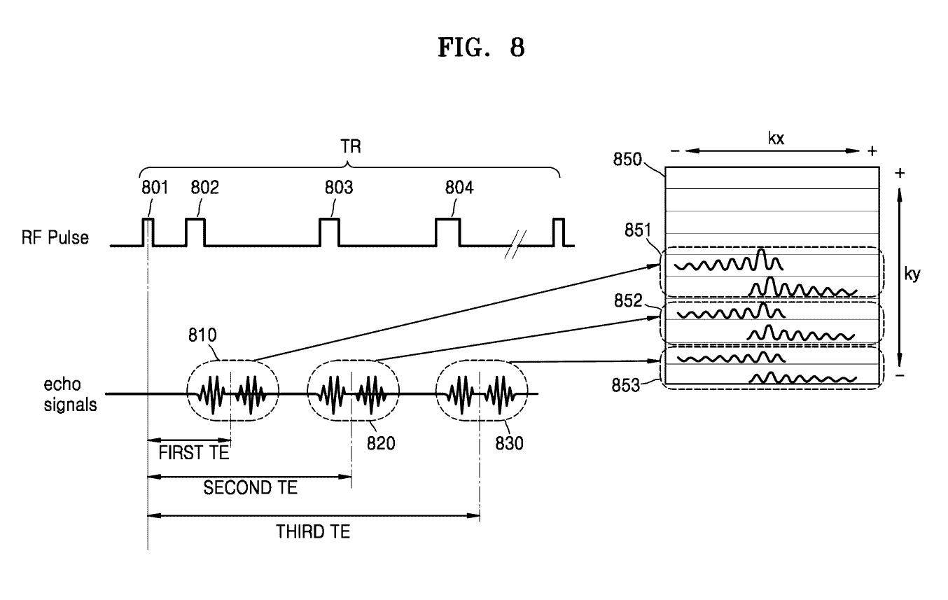

FIG. 8 is a diagram illustrating another example where the MR apparatus 200 reconstructs an MR image according to an exemplary embodiment.

Referring to FIG. 8, the controller 220 of the MRI apparatus 200 according to an exemplary embodiment may control the scanner 210 to emit one RF excitation pulse 801 and a plurality of refocusing pulses 802, 803, and 804 to an object during one TR based on an FAS method.

Also, the controller 220 may control the scanner 210 to receive dual-echo signals 810, 820, and 830 before and after TEs (i.e., a first TE, a second TE, and a third TE) for the plurality of refocusing pulses 810, 820, and 830. In this case, the controller 220 may sample the received dual-echo signals 810, 820, and 830 to correspond to different lines 851, 852, and 853 in a k-space 850. Also, the received dual-echo signals 810, 820, and 830 may be partial echo signals that are biased in different directions of a k-space 850.

The controller 220 may control the scanner 210 to sample dual-echo signals to correspond to discontinuous or continuous lines in the k-space 850 by controlling a phase encoding gradient magnetic field applied to the object. Also, the controller 220 may reconstruct at least one MR image based on the k-space 850, which is the same as that described with reference to FIGS. 5 through 7 and thus will not be described in detail.

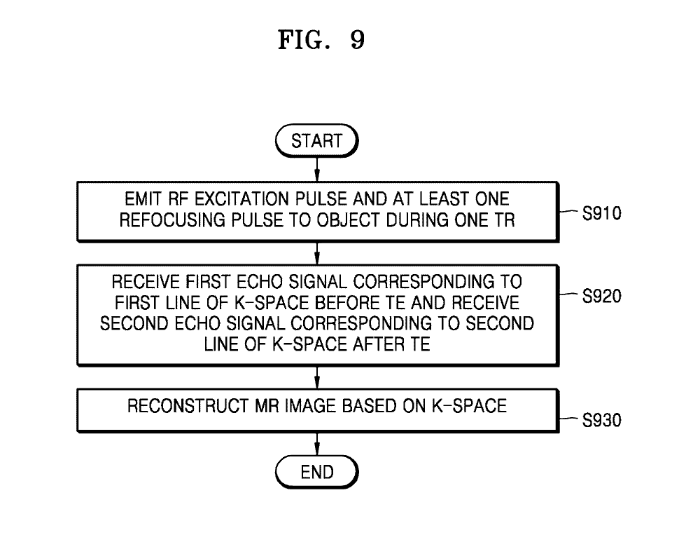

FIG. 9 is a flowchart of an operation method of the MRI apparatus 200 according to an exemplary embodiment. The operation method of the MRI apparatus 200 of FIG. 9 is related to the exemplary embodiments of FIGS. 1 through 8. Accordingly, although omitted, the description made with reference to FIGS. 1 through 8 may apply to the operation method of the MRI apparatus 200 of FIG. 9.

FIG. 9 is a flowchart of an operation method of the MRI apparatus 200 according to an exemplary embodiment.

Referring to FIG. 9, in operation S910, the MRI apparatus 200 emits an RF excitation pulse and at least one refocusing pulse to an object during one TR. The MRI apparatus 200 may emit one RF excitation pulse and one refocusing pulse to the object based on an SE method. The SE method may be a method of receiving an echo signal (i.e., an MR signal) by using magnetization in which when a 90°-RF excitation pulse and a 180°-refocusing pulse are applied to the object, atoms in the object precess.

In operation S920, the MRI apparatus 200 receives a first echo signal corresponding to a first line of a k-space before a TE and receives a second echo signal corresponding to a second line of the k-space after the TE. The TE may refer to a time at which an echo signal having a highest intensity is measured after an RF pulse is emitted to the object. Also, the first echo signal and the second echo signal may be partial echo signals that are biased in different directions of the k-space.

Accordingly, the MRI apparatus 200 may fill a part of the first line and a part of the second linen in the k-space by sampling the first echo signal and the second echo signal. For example, the first echo signal may be biased and sampled in a first direction (e.g., a negative (−) direction) of a kx-axis of the k-space, and the second echo signal may be biased and sampled in a second direction (e.g., a positive (+) direction) of the k-axis of the k-space.

According to an exemplary embodiment, the MRI apparatus 200 may control the scanner 210 to create a first readout gradient magnetic field and a second readout gradient magnetic field before and after the TE in order to respectively receive the first echo signal and the second echo signal that are biased and sampled in different directions. Each of the first and second readout gradient magnetic fields may be a gradient magnetic field corresponding to the kx-axis of the k-space, for example, a frequency encoding gradient magnetic field.

According to an exemplary embodiment, the MRI apparatus 200 may adjust the first readout gradient magnetic field and the second readout gradient magnetic field in order to receive the first echo signal and the second echo signal having highest intensities in a central region of the k-space. For example, the first readout gradient magnetic field may include a first bipolar gradient magnetic field for receiving the first echo signal corresponding to the central region of the k-space a predetermined period of time (e.g., Δt) before the TE, and the second readout gradient magnetic field may include a second bipolar gradient magnetic field for receiving the second echo signal corresponding to the central region of the k-space the predetermined period of time (e.g., Δt) after the TE. The MRI apparatus 200 may control the first echo signal and the second echo signal corresponding to the central region of the k-space not to lose their intensities by adjusting the predetermined period of time (e.g., Δt).

Also, according to an exemplary embodiment, the MRI apparatus 200 may adjust a position of the first line corresponding to the first echo signal in the k-space and a position of the second line corresponding to the second echo signal in the k-space by controlling a magnitude and a direction of a phase encoding gradient magnetic field. For example, the MRI apparatus 200 may control the phase encoding gradient magnetic field so that the first line and the second line are discontinuous in the k-space in order to reduce magnetic field inhomogeneity or phase discontinuity. Alternatively, the MRI apparatus 200 may control the phase encoding gradient magnetic field so that the first line and the second line are continuous in the k-space.

In operation S930, the MRI apparatus 200 reconstructs an MR image based on the k-space. The MRI apparatus 200 may reconstruct an MR image based on types of sampled data and non-sampled data in the k-space.

According to an exemplary embodiment, the MRI apparatus 200 may reconstruct an MR image based on a POCS method when the first line corresponding to the first echo signal in the k-space and the second line corresponding to the second echo signal in the k-space are discontinuous. In detail, the MRI apparatus 200 may reconstruct an MR image by interpolating pieces of data corresponding to non-sampled regions of the k-space based on a POCS method. The POCS method may be a method of interpolating pieces of data of non-sampled regions by repeatedly performing a process of reconstructing an MR image by using at least one projection data on the assumption that the non-sampled regions are regarded as missing data.

Alternatively, the MRI apparatus 200 may reconstruct an MR image based on a two-point Dixon method when the first line corresponding to the first echo signal in the k-space and the second line corresponding to the second echo signal in the k-space are continuous. In detail, the MRI apparatus 200 may reconstruct a first MR image from lines that are biased in a first direction of the k-space and may reconstruct a second MR image from lines that are biased in a second direction based on a two-point Dixon method. The two-point Dixon method may be a method of obtaining separated MR mages by using a phase difference between water and fat. Accordingly, in this case, the MRI apparatus 200 may obtain the first echo signals based on a first TE in which magnetization between water and fat is in-phase and may obtain the second echo signals based on a second TE in which magnetization between water and fat is out of phase.

In operation S910, when the MRI apparatus 200 emits one RF excitation pulse and a plurality of refocusing pulses to the object based on an FSE method, the MRI apparatus 200 may receive a plurality of dual-echo signals corresponding to the plurality of refocusing pulses. In this case, in operation S920, the MRI apparatus 200 may receive dual-echo signals corresponding to different lines in the k-space before and after a plurality of TEs. For example, when the MRI apparatus 200 emits N refocusing pulses to the object, the MRI apparatus 200 may receive N×2 echo signals. Also, the MRI apparatus 200 may sample the N×2 echo signals to correspond to N×2 lines in the k-space.

Exemplary embodiments may be implemented through non-transitory computer-readable recording media having recorded thereon computer-executable instructions and data. The instructions may be stored in the form of program codes, and when executed by a processor, generate a predetermined program module to perform a specific operation. Furthermore, when being executed by the processor, the instructions may perform specific operations according to the exemplary embodiments.

While one or more exemplary embodiments have been described with reference to the figures, it will be understood by one of ordinary skill in the art that various changes in form and details may be made therein without departing from the spirit and scope of the present disclosure as defined by the following claims. Accordingly, the above exemplary embodiments and all aspects thereof are examples only and are not limiting.

What is claimed is:

1. A magnetic resonance imaging (MRI) apparatus comprising:
a scanner configured to emit at least one radio frequency (RF) signal to an object during one repetition time (TR), and to receive echo signals emitted from the object; and
a controller configured to transmit one or more control signals to the scanner to control the scanner,
wherein the controller is further configured to
control the scanner to emit an RF excitation pulse and a refocusing pulse to the object during the one TR,
control the scanner to receive a first echo signal corresponding to a first line of a k-space before an echo time (TE), and to receive a second echo signal corresponding to a second line of the k-space after the TE, and
reconstruct a magnetic resonance (MR) image based on the k-space.

2. The MRI apparatus of claim 1, wherein the first echo signal comprises a first partial echo signal biased in a first direction of the k-space, and the second echo signal comprises a second partial echo signal biased in a second direction of the k-space.

3. The MRI apparatus of claim 2, wherein the controller is further configured to bias and sample the first echo signal in the first direction corresponding to the first line of the k-space and bias and sample the second echo signal in the second direction corresponding to the second line of the k-space.

4. The MRI apparatus of claim 3, wherein the controller is further configured to control the scanner to apply a first readout gradient magnetic field to the object for receiving the first echo signal, and a second readout gradient magnetic field to the object for receiving the second echo signal.

5. The MRI apparatus of claim 4, wherein
the first readout gradient magnetic field comprises a first bipolar gradient magnetic field for receiving an echo signal corresponding to a central region of the k-space a predetermined period of time before the TE, and
the second readout gradient magnetic field comprises a second bipolar gradient magnetic field for receiving an echo signal corresponding to the central region of the k-space the predetermined period of time after the TE.

6. The MRI apparatus of claim 1, wherein the first line is discontinuous with the second line in the k-space.

7. The MRI apparatus of claim 6, wherein the controller is further configured to reconstruct the MR image by interpolating non-sampled regions in the k-space, based on a projection of convex set (POCS) method.

8. The MRI apparatus of claim 1, wherein the first line is continuous with the second line in the k-space.

9. The MRI apparatus of claim 8, wherein the controller is further configured to reconstruct a first MR image from lines biased in a first direction of the k-space, and reconstruct a second MR image from lines biased in a second direction of the k-space, based on a two-point Dixon method.

10. The MRI apparatus of claim 9, wherein
the first echo signal is received before a first TE in which magnetization between water and fat in the object is in-phase, and
the second echo signal is received after a second TE in which magnetization between water and fat in the object is out of phase.

11. An operation method of a magnetic resonance imaging (MRI) apparatus, the operation method comprising:
emitting a radio frequency (RF) excitation pulse and a refocusing pulse to an object during one repetition time (TR);
receiving a first echo signal corresponding to a first line of a k-space before an echo time (TE), and receiving a second echo signal corresponding to a second line of the k-space after the TE; and
reconstructing a magnetic resonance (MR) image based on the k-space.

12. The operation method of claim 11, wherein the first echo signal comprises a first partial echo signal biased in a first direction of the k-space, and the second echo signal comprises a second partial echo signal biased in a second direction of the k-space.

13. The operation method of claim 12, wherein the receiving of the first echo signal and the second echo signal comprises:
biasing and sampling the first echo signal in the first direction corresponding to the first line of the k-space; and
biasing and sampling the second echo signal in the second direction corresponding to the second line of the k-space.

14. The operation method of claim 13, further comprising applying a first readout gradient magnetic field to the object for receiving the first echo signal, and a second readout gradient magnetic field to the object for receiving the second echo signal.

15. The operation method of claim 14, wherein
the first readout gradient magnetic field comprises a first bipolar gradient magnetic field for receiving an echo signal corresponding to a central region of the k-space a predetermined period of time before the TE, and
the second readout gradient magnetic field comprises a second bipolar gradient magnetic field for receiving an echo signal corresponding to the central region of the k-space the predetermined period of time after the TE.

16. The operation method of claim 11, wherein the first line is discontinuous with the second line in the k-space.

17. The operation method of claim 16, wherein the reconstructing of the MR image comprises reconstructing the MR image by interpolating non-sampled regions in the k-space, based on a projection of convex set (POCS) method.

18. The operation method of claim 11, wherein the first line is continuous with the second line in the k-space.

19. The operation method of claim 18, wherein the reconstructing of the MR image comprises reconstructing a first MR image from lines biased in a first direction of the k-space and reconstructing a second MR image from lines biased in a second direction of the k-space, based on a two-point Dixon method.

20. A computer-readable recording medium having embodied thereon a program for executing the operation method of claim 11.
